(19) United States
(12) Patent Application Publication
(10) Pub. No.: US 2021/0017067 A1
(43) Pub. Date: Jan. 21, 2021

(54) CONDUCTIVE PASTE, METHOD, ELECTRODE AND SOLAR CELL

(71) Applicant: Johnson Matthey Public Limited Company, London (GB)

(72) Inventors: Kirill ARAPOV, Maastricht (NL); Beatriz CELA GREVEN, Maastricht (NL); Edwin Peter Kennedy CURRIE, Maastricht (NL); Roland KATZBACH, Maastricht (NL)

(21) Appl. No.: 16/980,517

(22) PCT Filed: Mar. 18, 2019
(86) PCT No.: PCT/GB2019/050754

§ 371 Date: Sep. 14, 2020

(30) Foreign Application Priority Data
Mar. 21, 2018 (GB) 1804472.7

(51) Int. Cl. C03C 8/18; C03C 4/14; C03C 8/02; C03C 3/12; H01L 31/0224

(52) U.S. Cl. CPC C03C 8/18; C03C 4/14; H01L 31/022425; C03C 3/122; C03C 8/02

(57) ABSTRACT

A conductive paste for forming a conductive track or coating on a substrate, the paste comprising a solids portion dispersed in an organic vehicle, the solids portion comprising electrically conductive material and an inorganic particle mixture; wherein the inorganic particle mixture comprises particles of glass frit and substantially crystalline particles of one or more metal compounds; and wherein the glass frit comprises at least 90 mol % Te O₂.

### FIELD OF THE INVENTION

The present invention relates to conductive pastes which are particularly suitable for use in solar cells and methods for making those pastes, to a method of manufacturing a conductive track or coating on a surface e.g. of a solar cell, and to an electrode and to a solar cell having such an electrode formed on a surface thereof.

### BACKGROUND OF THE INVENTION

Conductive (e.g. silver-containing) pastes are routinely used in the preparation of conductive tracks for solar cells, such as silicon solar cells. The pastes typically comprise conductive (e.g. silver) powder, glass frit, and sometimes one or more additional additives, all dispersed in an organic vehicle. In the manufacture of solar cells, such a paste is typically applied to a semi-conductor substrate (e.g. a wafer) via screen-printing and is subsequently fired (i.e. subjected to heat treatment). The glass frit has several roles. During firing, it becomes a molten phase and so acts to bond the conductive track to the semiconductor wafer. However, the glass frit is also important in etching away the anti-reflective or passivation layer (usually silicon nitride) provided on the surface of the semiconductor wafer, to permit direct contact between the conductive track and the semiconductor. The glass frit is typically also important in forming an ohmic contact with the semiconductor wafer.

Glass frits which find use in conductive paste applications often contain lead. However, the use of lead is undesirable due to environmental and toxicity concerns.

The quality of the contact between the conductive track and the semiconductor wafer is instrumental in determining the efficiency of the final solar cell. The best glass frits need to be optimised to flow at the correct temperature, and to provide the correct degree of etching of the antireflective layer. If too little etching is provided, then there will be insufficient contact between the semiconductor wafer and the conductive track, resulting in a high contact resistance. Conversely, excessive etching may lead to deposition of large islands of silver in the semiconductor, disrupting its p-n junction and thereby reducing its ability to convert solar energy into electrical energy.

Much recent attention has focussed on improving the glass frit materials included in conductive pastes for photovoltaic cells, to provide a good balance of properties. Alternatives to glass frits have also been proposed, such as mixtures of crystalline oxides. Conductive pastes comprising conductive powder, glass frit, and sometimes one or more additional additives, all dispersed in an organic vehicle, are also used to form conductive tracks or conductive coatings in a range of other electronics applications, including passive electronic components, e.g. in terminal electrodes for zinc oxide varistor components, terminations for MLCC (multi-layer ceramic capacitors), electrodes on TCO (transparent conductive oxide) coated glass substrate, conductive layers on NTC (negative temperature coefficient) thermistors, metallization of functional piezoceramics; and automotive applications including antennae and heatable mirrors, windscreens and backlites.

### SUMMARY OF THE INVENTION

There remains a need for compositions suitable for use in conductive pastes for solar cells which provide an excellent (lowered) contact resistance without negatively influencing the p-n junction of a solar cell, and which flow at a suitable temperature for firing the conductive paste during manufacture of a solar cell. Furthermore, there remains a need for conductive pastes which do not contain toxic components, such as lead, and which the manufacturing, recycling and disposal thereof has a reduced impact on the environment.

The present inventors have surprisingly found that the use of glass frit combined with substantially crystalline particles of one or more metal compounds may provide a conductive paste with superior properties.

Accordingly, a first aspect of the present invention provides a conductive paste for forming a conductive track or coating on a substrate, the paste comprising a solids portion dispersed in an organic vehicle, the solids portion comprising electrically conductive material and an inorganic particle mixture; wherein the inorganic particle mixture comprises particles of glass frit and substantially crystalline particles of one or more metal compounds; and wherein the glass frit comprises at least 90 mol % TeO₂.

Conductive pastes according to the present invention, which comprise a combination of glass frit and substantially crystalline particles of one or more metal compounds, offer a number of advantages over other conductive pastes for solar cell applications. When used in solar cell applications, conductive pastes of the present invention have been found to provide solar cells with improved (i.e. lower) series resistance and hence improved conductivity.

According to a second aspect of the present invention, there is provided a method of preparing a conductive paste according to the first aspect, comprising mixing an organic vehicle and the components of the solids portion, in any order.

According to a third aspect of the present invention, there is provided a method for the manufacture of an electrode of a solar cell, the method comprising applying a conductive paste as defined in the first aspect to a semiconductor substrate, and firing the applied conductive paste.

According to a fourth aspect of the present invention, there is provided an electrode for a solar cell, the electrode comprising a conductive track on a semiconductor substrate, wherein the conductive track is obtained or obtainable by firing a paste as defined in the first aspect on the semiconductor substrate.

According to a fifth aspect of the present invention, there is provided a solar cell comprising an electrode as defined in the fourth aspect.

According to a sixth aspect of the present invention, there is provided the use of a conductive paste as defined in the first aspect in the manufacture of an electrode of a solar cell.

According to a seventh aspect, there is provided the use of an inorganic particle mixture in a conductive paste to improve the series resistance of a solar cell, wherein the inorganic particle mixture comprises particles of glass frit and substantially crystalline particles of one or more metal compounds and wherein the glass frit comprises at least 90 mol % TeO₂.

### BRIEF DESCRIPTION OF DRAWINGS

FIG. 1 shows an example of a firing curve for a solar cell prepared in the Examples.

### DETAILED DESCRIPTION

Preferred and/or optional features of the invention will now be set out. Any aspect of the invention may be combined with any other aspect of the invention unless the context demands otherwise. Any of the preferred and/or optional features of any aspect may be combined, either singly or in combination, with any aspect of the invention unless the context demands otherwise.

For example, the discussion of the inorganic particle mixture content, raw materials and particle size distribution is applicable to the aspects of the invention relating to pastes and methods equally.

Where ranges are specified herein it is intended that each endpoint of the range is independent. Accordingly, it is expressly contemplated that each recited upper endpoint of a range is independently combinable with each recited lower endpoint, and vice versa.

### Solids Portion

Conductive pastes of the present invention include an organic vehicle and a solids portion. The solids portion includes an electrically conductive material and an inorganic particle mixture. The inorganic particle mixture comprises particles of glass frit and substantially crystalline particles of one or more metal compounds. Various embodiments of the solids portion will be discussed in greater detail below, as will various methods of utilising them to form a conductive paste.

The solids portion may constitute at least 80 wt %, at least 85 wt %, at least 87 wt % or at least 90 wt % of the conductive paste. The solids portion may constitute 98 wt % or less, 95 wt % or less, or 91 wt % or less of the conductive paste. In some embodiments, the conductive paste may comprise ≥80 to ≤98 wt % of the solids portion.

### Conductive Material

In some embodiments, the solids portion includes ≥80 to ≤99.9 wt % of electrically conductive material (with respect to total weight of the solids portion). In some embodiments, the electrically conductive material is a metallic silver powder. However, the invention is not particularly limited to metallic silver powders and powders of other electrically conductive materials are contemplated.

### Inorganic Particle Mixture

The solids portion of the conductive paste of the present invention may include ≥0.1 to ≤15 wt % of the inorganic particle mixture (with respect to total weight of the solids portion). The solids portion of the conductive paste may include at least 0.5 wt % or at least 1 wt % of the inorganic particle mixture. The solids portion of the conductive paste may include 10 wt % or less, 7 wt % or less or 5 wt % or less of the inorganic particle mixture.

The inorganic particle mixture comprises particles of glass frit and substantially crystalline particles of one or more metal compounds, wherein the glass frit comprises at least 90 mol % TeO₂. Detailed descriptions of each component of the inorganic particle mixture are set out hereinafter.

It will be understood by the skilled reader that a glass material is not synonymous with an amorphous material, or even an amorphous region within a crystalline material. A glass material exhibits a softening point and does not exhibit a melting point. A glass material exhibits a glass transition. While glasses may include some crystalline domains (they may not be entirely amorphous) these are different from the discrete substantially crystalline particles of one or more metal compounds required by the present invention.

The term “substantially crystalline” means crystalline material which has long-range structural order of atoms through the material. Such a material does not exhibit a glass transition. This contrasts with, for example, amorphous or glassy materials. Substantially crystalline materials exhibit a melting point.

The person skilled in the art will be able to select suitable methods to determine whether a material is crystalline or amorphous. For example, the person skilled in the art may use X-ray diffraction (XRD) methods. An amorphous or glass material will not produce distinct peaks in an XRD pattern. On the contrary an amorphous or glass material will produce broad signals in an XRD pattern. A substantially crystalline material will give rise to multiple distinct peaks in an XRD pattern.

In some embodiments, the inclusion of the inorganic particle mixture in the paste may provide improved contact resistance in solar cells prepared using the conductive paste. In some embodiments, the use of a conductive paste comprising the inorganic particle mixture in the preparation of a solar cell may provide a solar cell having increased efficiency. In particular, it has been surprisingly found that the use of the conductive paste of the present invention in the preparation of a solar cell may provide a solar cell having increased efficiency compared to a solar cell prepared using a paste which comprises an inorganic particle mixture having the same overall chemical composition but provided as only glass frit or only as a mixture of crystalline metal compounds.

The inorganic particle mixture may consist essentially of particles of glass frit as described herein and particles of a substantially crystalline material as described herein.

The inorganic particle mixture may comprise particles of glass frit in an amount of at least 25 wt. %, for example, in an amount of at least 40 wt %, at least 45 wt % or at least 50 wt % (with respect to total weight of the inorganic particle mixture). The inorganic particle mixture may comprise particles of glass frit in an amount of 75 wt % or less, for example, 70 wt % or less, 65 wt % or less, or 60 wt % or less. In some embodiments, the inorganic particle mixture may comprise 40 to ≤70 wt % of particles of glass frit.

The inorganic particle mixture may comprise substantially crystalline particles in a total amount of at least 20 wt %, for example, in an amount of at least 25 wt. %, at least 30 wt. %, at least 35 wt. % or at least 40 wt % (with respect to total weight of the inorganic particle mixture). The inorganic particle mixture may comprise substantially crystalline particles in a total amount of 75 wt % or less, for example, 60 wt % or less, 55 wt % or less, or 50 wt % or less. In some embodiments, the inorganic particle mixture may comprise 35 to ≤55 wt %.

The glass frit of the inorganic particle mixture comprises at least 90 mol % TeO₂. In some embodiments, the glass frit may comprise greater than 90 mol % TeO₂. The glass frit may comprise at least 91 mol % TeO₂, preferably at least 92 mol % TeO₂, more preferably at least 95 mol % TeO₂.

The glass frit compositions described herein are given as mole percentages, on an oxide basis. These mole percentages are with respect to the total molar composition of the glass frit. The mole percentages are the percentages of the components used as starting materials in preparation of the glass frit compositions, on an oxide basis. As the skilled person will understand, starting materials other than oxides may be used in preparing the glass frits of the present invention. Where a non-oxide starting material is used to supply an oxide of a particular element to the glass frit composition, an appropriate amount of starting material is used to supply an equivalent molar quantity of the element had the oxide of that element been supplied at the recited mol %. This approach to defining glass frit compositions is typical in the art. As the skilled person will readily understand, volatile species (such as oxygen) may be lost during the manufacturing process of the glass frit, and so the composition of the resulting glass frit may not correspond exactly to the weight percentages of starting materials, which are given herein on an oxide basis. Analysis of a fired glass frit by a process known to those skilled in the art, such as Inductively Coupled Plasma Emission Spectroscopy (ICP-ES), can be used to calculate the starting components of the glass frit composition in question.

The glass frit may contain oxides of additional elements. In some embodiments, the glass frit may comprise an alkali metal oxide, an alkaline earth metal oxide, an oxide of cerium, an oxide of bismuth, or mixtures thereof. The alkali metal oxide may be Li₂O, Na₂O, K₂O, or mixtures thereof. In some embodiments, the glass frit contains Li₂O and Na₂O. The alkaline earth metal oxide may be BaO, CaO, MgO, or mixtures thereof. The oxide of cerium may be Ce₂O₃ or CeO₂. The oxide of bismuth may be Bi₂O₃.

The glass frit may include Li₂O. The glass frit may include at least 0.1 mol %, at least 1 mol %, or at least 3 mol % of Li₂O. The glass frit may include 10 mol % or less, 9 mol % or less, or 8 mol % or less of Li₂O. For example, the glass frit may include ≥3 to ≤8 mol % of Li₂O.

The glass frit may include Na₂O. The glass frit may include at least 0.1 mol %, at least 1 mol %, or at least 3 mol % of Na₂O. The glass frit may include 10 mol % or less, 9 mol % or less or 8 mol % or less of Na₂O. For example, the glass frit may include ≥3 to ≤8 mol % of Na₂O.

The glass frit may include K₂O. The glass frit may include at least 0.1 mol %, at least 1 mol %, or at least 3 mol % of K₂O. The glass frit may include 10 mol % or less, 9 mol % or less, or 8 mol % or less of K₂O. For example, the glass frit may include ≥3 to ≤8 mol % of K₂O.

The glass frit may include BaO. The glass frit may include at least 0.1 mol %, at least 1 mol %, at least 2 mol %, at least 4 mol % or at least 6 mol % of BaO. The glass frit may include 10 mol % or less, 9 mol % or less, 8 mol % or less or 7 mol % or less of BaO. For example, the glass frit may include ≥0.1 to ≤10 mol % of BaO.

The glass frit may include CaO. The glass frit may include at least 0.1 mol %, at least 1.0 mol %, at least 2 mol %, at least 4 mol % or at least 6 mol % of CaO. The glass frit may include 10 mol % or less, 9 mol % or less, 8 mol % or less or 7 mol % or less of CaO. For example, the glass frit may include ≥0.1 to ≤10 mol % of CaO.

The glass frit may include MgO. The glass frit may include at least 0.1 mol %, at least 1 mol %, at least 2 mol %, at least 4 mol % or at least 6 mol % of MgO. The glass frit may include 10 mol % or less, 9 mol % or less, 8 mol % or less or 7 mol % or less of MgO. For example, the glass frit may include ≥0.1 to ≤10 mol % of MgO.

The glass frit may include Ce₂O₃. The glass frit may include at least 0.1 mol %, at least 0.5 mol %, at least 1 mol %, at least 2 mol % or at least 4 mol % of Ce₂O₃. The glass frit may include 10 mol % or less, 8 mol % or less, 6 mol % or less or 5 mol % or less of Ce₂O₃. For example, the glass frit may include ≥0.1 to ≤10 mol % of Ce₂O₃.

The glass frit may include Bi₂O₃. The glass frit may include at least 0.1 mol %, at least 0.5 mol %, at least 1 mol %, at least 2 mol % or at least 4 mol % of Bi₂O₃. The glass frit may include 10 mol % or less, 8 mol % or less, 6 mol % or less or 5 mol % or less of Bi₂O₃. For example, the glass frit may include ≥0.1 to ≤10 mol % of Bi₂O₃.

The glass frit may include further components, such as further oxide components. The glass frit may include at least 0.1 mol %, at least 0.5 mol %, at least 1 mol %, at least 2 mol % or at least 4 mol % in total of further components. The glass frit may include 10 mol % or less, 8 mol % or less, 6 mol % or less or 5 mol % or less in total of further components. The further components may be one or more selected from the group consisting of Ge₂, Zr₂, CuO, Al₂O₃, B₂O₃, WO₃, MO₃, ZnO, Al₂O₃, RuO₂, PdO, V₂O₅ and P₂O₅.

In some embodiments, the glass frit may be substantially free of lead-oxide and/or substantially free of silicon oxide.

As used herein, the term “substantially free of” in relation to glass frit composition means that the glass frit has a total content of the recited component of less than or equal to 1 mol %. As will be readily understood by the skilled person, during manufacture of glass frit particles, the glass composition may be contaminated with low levels of impurities. For example, in a melt/quench glass forming process, such impurities may derive from refractory linings of vessels employed in the melting step. Thus, whilst a total absence of a particular component may be desirable, in practice this may be difficult to achieve. As used herein in relation to glass frit, the term “no intentionally added X”, where X is a particular component, means that no raw material was employed in the manufacture of the glass frit which was intended to deliver X to the final glass composition, and the presence of any low levels of X in the glass frit composition is due to contamination during manufacture.

In some embodiments, the glass frit may comprise less than 0.5 mol %, preferably less than 0.25 mol %, more preferably less than 0.05 mol %, most preferably less than 0.01 mol % PbO.

In some embodiments, the glass frit does not include any intentionally added lead.

In some embodiments, the glass frit may comprise less than 0.5 mol %, preferably less than 0.25 mol %, more preferably less than 0.05 mol %, most preferably less than 0.01 mol % SiO₂. In some embodiments, the glass frit does not include any intentionally added silicon.

Typically, the glass frit is prepared by mixing together the starting materials, melting them to form a molten glass mixture and then quenching the molten mixture to form the glass frit. The process may further comprise milling the frit to provide the desired particle size.

The skilled person is aware of alternative suitable methods for preparing glass frit. Suitable alternative methods include, sol-gel processes and spray pyrolysis.

Whilst the glass frits according to the present invention are described as comprising oxides of respective elements, the choice of starting material used to prepare the frit may be any compound which decomposes to an oxide upon formation of a glass. For example, suitable starting material compounds used to prepare glass frits may be oxides, carbonates, nitrates, hydrogen carbonates, oxalates, acetates and/or formates of said element. Some specific starting material compounds which may be used in forming the glass frit are Li₂O, Li₂CO₃, Bi₂O₃, Bi₅O(OH)(NO₃)₄, Ce₂O₃, CeO₂, Na₂O and Na₂CO₃.

The glass frit may be milled or ground to provide a desired particle size and a desired particle morphology.

The inorganic particle mixture further comprises substantially crystalline particles of one or more metal compounds. Since the particles are substantially crystalline, they do not exhibit a glass transition.

For the avoidance of doubt, the term “metal”, used herein in relation to the substantially crystalline particles of one or more metal compounds, includes metalloids, such as boron, silicon, germanium, arsenic, antimony and tellurium. Thus, the substantially crystalline particles of one or more metal compounds may comprise a compound of tellurium, and/or a compound of boron, for example.

The particulate nature of the substantially crystalline particles of one or more metal compounds means that discrete, separate or individual particles of each of the one or more metal compounds are present in the inorganic particle mixture.

In some embodiments of the invention the inorganic particle mixture comprises substantially crystalline particles of more than one metal compound, in some embodiments two or more metal compounds, in some embodiments three or more, four or more, five or more or six or more different metal compounds.

The substantially crystalline particles of one or more metal compounds may include a compound of lithium, sodium, potassium, barium, cerium, bismuth, tungsten, molybdenum, vanadium, calcium, magnesium, manganese, silver, boron, zinc, zirconium, tellurium, silicon, chromium or mixtures thereof. The one or more metal compounds may be selected from metal oxides, carbonates, nitrates, hydrogen carbonates, oxalates, acetates and/or formates. Where the one or more metal compounds include non-oxide compounds, preferably the non-oxide compounds are compounds which would decompose to oxides on firing. The person skilled in the art will be able to select other suitable metal compounds.

Where the substantially crystalline particles comprise two or more metal compounds, the metal compounds may be different types of compound, for instance the substantially crystalline particles may comprise an oxide of one metal and a carbonate of a different metal; e.g. Li₂O and Na₂CO₃. In some embodiments, the substantially crystalline particles may comprise multiple compounds of the same type but be compounds of different metals; for example, Li₂O and Na₂O, or Li₂CO₃ and Na₂CO₃. In some embodiments, the substantially crystalline particles may comprise a mixture of metal compounds comprising the same metal, for example, a mixture of an oxide and a carbonate of the same metal, e.g. Li₂O and Li₂CO₃.

Some specific metal compounds which may be included in the substantially crystalline particles of the inorganic particle mixture include Li₂O, Li₂CO₃, Bi₂O₃, Bi₅O(OH)(NO₃)₄, Ce₂O₃, CeO₂, Na₂O, Na₂CO₃, TeO₂, Bi₂O₃, Ce₂O₃, SiO₂, ZnO, MoO₃, Cr₂O₃ and WO₃.

In some embodiments, any or all of the one or more metal compounds may comprise multiple metal atoms or ions. For example, in some embodiments, the one or more metal compounds may comprise a compound having the general formula AₓB_{y}O_{z} where A is metal and where B is a metal different to A, where 0<x≤2, y is an integer and z is an integer.

Selection of the one or metal compounds of the substantially crystalline particles may be guided by the desired flow behaviour on firing. The inventors have found certain mixtures particularly suitable. For example, the one or more metal compounds may include a source of alkali metal, preferably lithium (for example, LiCO₃ or Li₂O) and a source of bismuth (for example, Bi₂O₃ or Bi₅O(OH)(NO₃)₄).

When the inorganic particle mixture contains substantially crystalline particles of more than one metal compound, the metal compounds may be mixed (for example, by co-milling) prior to incorporation into a conductive paste and/or prior to mixing with glass frit to form the inorganic particle mixture. In one embodiment, the substantially crystalline particles of one or more metals may be milled in combination with the glass frit before being incorporated into the conductive paste.

The inorganic particle mixture may comprise ≥0 wt. % to ≤10 wt. % substantially crystalline particles of a tellurium compound (with respect to total weight of the inorganic particle mixture). In some embodiments, the inorganic particle mixture may comprise 5 wt % or less, 3 wt % or less, 1 wt. % or less of substantially crystalline particles of a tellurium compound. In some embodiments, the tellurium compound may be tellurium oxide (TeO₂). For example, the inorganic particle mixture may comprise ≥0 wt. % to ≤10 wt % substantially crystalline particles of tellurium oxide.

The inorganic particle mixture may comprise ≥1 wt. % to ≤9 wt. % substantially crystalline particles of a lithium compound (with respect to total weight of the inorganic particle mixture). In some embodiments, the inorganic particle mixture may comprise at least 1 wt. %, at least 2 wt. %, at least 3 wt. % or at least 4 wt. % of substantially crystalline particles of a lithium compound. In some embodiments, the inorganic particle mixture may comprise 8 wt % or less, 5 wt % or less of substantially crystalline particles of a lithium compound (Li₂CO₃). In some embodiments, the lithium compound may be lithium carbonate. For example, the inorganic particle mixture may comprise ≥1 wt. % to ≤9 wt. % substantially crystalline particles of lithium carbonate.

The inorganic particle mixture may comprise ≥0 wt % to ≤5 wt % substantially crystalline particles of a sodium compound (with respect to total weight of the inorganic particle mixture). In some embodiments, the inorganic particle mixture may comprise at least 1 wt %, at least 2 wt % or at least 3 wt % of substantially crystalline particles of a sodium compound. In some embodiments, the inorganic particle mixture may comprise 4 wt % or less of substantially crystalline particles of a sodium compound. In some embodiments, the sodium compound may be sodium carbonate (Na₂CO₃). For example, the inorganic particle mixture may comprise ≥0 wt % to ≤5 wt % substantially crystalline particles of sodium carbonate.

The inorganic particle mixture may comprise 0 wt. % to ≤5 wt. % substantially crystalline particles of a barium compound (with respect to total weight of the inorganic particle mixture). In some embodiments, the inorganic particle mixture may comprise at least 1 wt. %, at least 2 wt. %, at least 3 wt. % or at least 4 wt. % of substantially crystalline particles of a barium compound. In some embodiments, the inorganic particle mixture may comprise 4.5 wt % or less of substantially crystalline particles of a barium compound. In some embodiments, the barium compound may be barium carbonate (BaCO₃). For example, the inorganic particle mixture may comprise ≥0 wt % to ≤5 wt % substantially crystalline particles of barium carbonate.

The inorganic particle mixture may comprise ≥0 wt % to ≤9 wt % substantially crystalline particles of a cerium compound (with respect to total weight of the inorganic particle mixture). In some embodiments, the inorganic particle mixture may comprise at least 1 wt %, at least 2 wt %, at least 4 wt %, or at least 5 wt % of substantially crystalline particles of a cerium compound. In some embodiments, the inorganic particle mixture may comprise 8 wt % or less, or 7 wt % or less of substantially crystalline particles of a cerium compound. In some embodiments, the cerium compound may be cerium (Ill) oxide (Ce₂O₃). For example, the inorganic particle mixture may comprise ≥0 wt. % to ≤9 wt. % substantially crystalline particles of cerium (Ill) oxide.

The inorganic particle mixture may comprise ≥15 wt % to ≤35 wt % substantially crystalline particles of a bismuth compound (with respect to total weight of the inorganic particle mixture). In some embodiments, the inorganic particle mixture may comprise at least 20 wt %, at least 25 wt %, at least 27 wt %, or at least 28 wt % of substantially crystalline particles of a bismuth compound. In some embodiments, the inorganic particle mixture may comprise 30 wt % or less of substantially crystalline particles of a bismuth compound. In some embodiments, the bismuth compound may be bismuth oxide (Bi₂O₃). For example, the inorganic particle mixture may comprise ≥15 wt % to ≤35 wt % substantially crystalline particles of bismuth oxide.

The inorganic particle mixture may comprise ≥0 wt % to ≤10 wt % substantially crystalline particles of a zinc compound (with respect to total weight of the inorganic particle mixture). In some embodiments, the zinc compound may be zinc oxide (ZnO). For example, the inorganic particle mixture may comprise ≥0 wt % to ≤10 wt % substantially crystalline particles of zinc oxide.

The inorganic particle mixture may comprise ≥0 wt % to ≤10 wt % substantially crystalline particles of a boron compound (with respect to total weight of the inorganic particle mixture). In some embodiments, the boron compound may be boron oxide (B₂O₃). For example, the inorganic particle mixture may comprise ≥0 wt % to ≤10 wt % substantially crystalline particles of boron oxide.

The inorganic particle mixture may comprise ≥0 wt % to ≤9 wt % substantially crystalline particles of a tungsten compound (with respect to total weight of the inorganic particle mixture). In some embodiments, the tungsten compound may be tungsten oxide (WO₃). For example, the inorganic particle mixture may comprise 0 wt. % to ≤9 wt % substantially crystalline particles of tungsten oxide.

The inorganic particle mixture may comprise ≥0 wt % to ≤9 wt % substantially crystalline particles of a molybdenum compound (with respect to total weight of the inorganic particle mixture). In some embodiments, the molybdenum compound may be molybdenum oxide (MoO₃). For example, the inorganic particle mixture may comprise ≥0 wt % to ≤9 wt % substantially crystalline particles of molybdenum oxide.

The inorganic particle mixture may comprise ≥0 wt % to ≤9 wt % substantially crystalline particles of a zirconium compound (with respect to total weight of the inorganic particle mixture). In some embodiments, the zirconium compound may be zirconium oxide (Zr₂). For example, the inorganic particle mixture may comprise ≥0 wt % to ≤9 wt % substantially crystalline particles of zirconium oxide.

The inorganic particle mixture may comprise ≥0 wt % to ≤9 wt % substantially crystalline particles of a silver compound (with respect to total weight of the inorganic particle mixture). For example, the inorganic particle mixture may comprise ≥0 wt % to ≤9 wt % substantially crystalline particles of silver oxide.

In some embodiments, the inorganic particle mixture may comprise substantially crystalline particles of any lead compounds in a total amount of less than 1 wt %, for example, the inorganic particle mixture may comprise less than 0.5 wt %, less than 0.1 wt %, less than 0.05 wt. %, less than 0.01 wt. % or less than 0.005 wt % substantially crystalline particles of any lead compounds (with respect to total weight of the inorganic particle mixture).

In some embodiments, the inorganic particle mixture may comprise substantially crystalline particles of any silicon compounds in a total amount of less than 2 wt %, for example, the inorganic particle mixture may comprise less than 1 wt. %, less than 0.5 wt. %, less than 0.1 wt %, less than 0.05 wt %, less than 0.01 wt % or less than 0.005 wt % substantially crystalline particles of any silicon compounds (with respect to total weight of the inorganic particle mixture).

The particles of the inorganic particle mixture (i.e. the particles of the glass frit and the substantially crystalline particles) can be defined in terms of their D₅₀ and D₉₀ particle size. The terms “D₅₀ particle size” and “Do particle size” herein refer to particle size distribution. A value for D₅₀ and D₉₀ particle size corresponds to the particle size value below which 50% and 90%, respectively, by volume, of the total particles in a particular sample lie. The D₅₀ and D₉₀ particle size may be determined using a laser diffraction method (e.g. using a Malvern Mastersizer 2000).

In some embodiments, the inorganic particle mixture has a D₉₀ particle size of less than or equal to 5 μm, preferably less than or equal to 3 μm, more preferably less than or equal to 2 μm. In some embodiments, the inorganic particle mixture has a D₉₀ particle size of at least 1 μm.

In some embodiments, with the caveat that D₉₀ is always bigger than Do, the inorganic particle mixture has a D₅₀ particle size of less than or equal to 2 μm, preferably less than or equal to 1 μm, more preferably less than or equal to 0.5 m. In some embodiments, the inorganic particle mixture has a D₉₀ particle size of at least 0.2 m.

The particle size distribution of the substantially crystalline particles of one more metal compounds is preferably similar to that of the glass frit. When the crystalline metal compounds of one or more metals are co-milled in combination with the glass frit to produce the inorganic particle mixture, the milling step can be tuned to produce an inorganic particle mixture with the desired particle size and particle size distribution. The skilled person will be able to select milling conditions to tune the particle size distribution of the inorganic particle mixture.

The person skilled in the art will be aware of suitable methods and instrumentation for calculating particle size distributions. For example laser diffraction methods can be used such as use of a Malvern Mastersizer 2000.

### Organic Vehicle

The solids portion of the conductive paste of the present invention is dispersed in an organic vehicle.

In some embodiments, the conductive paste consists of the solids portion and the organic vehicle.

The organic vehicle typically comprises an organic solvent with one or more additives dissolved or dispersed therein. As the skilled person will readily understand, the components of the organic vehicle are typically chosen to provide suitable consistency and rheology properties to permit the conductive paste to be printed onto a semiconductor substrate, and to render the paste stable during transport and storage. For example, where it is intended that a paste will be printed by screen printing or stencil printing, the organic vehicle may be a shear thinning fluid, which fluid may have a high viscosity when at rest but reduced viscosity when subjected to shear stress.

Examples of suitable organic solvents for the organic vehicle include one or more solvents selected from the group consisting of butyl diglycol, butyldiglycol acetate, terpineol, diethylene glycol dibutyl ether, tripropyleneglycol monomethylether, Texanol®, dimethyl adipate, 2-(2-methoxypropoxy)-1-propanol and mixtures thereof.

Examples of suitable additives include dispersants to assist dispersion of the solids portion in the paste, viscosity/rheology modifiers, thixotropy modifiers, wetting agents, thickeners, stabilisers and surfactants.

For example, the organic vehicle may comprise one or more additives selected from the group consisting of Disperbyk 111, Disperbyk 145, Duomeen TDO, fatty acid amides waxes (such as Thixatrol Max, Crayvallac Super), rosin and its derivatives, acrylic resins (such as Neocryl @), ethyl cellulose, cellulose acetate butyrate, and polyvinylbutyral (such as Mowital B grade).

The organic vehicle may constitute, for example, at least 2 wt %, at least 5 wt %, at least 9 wt % of the conductive paste (with respect to total weight of the conductive paste). The organic vehicle may constitute 20 wt % or less, 15 wt % or less, 13 wt % or less, or 10 wt % or less of the conductive paste. In some embodiments, the conductive paste may comprise 2 to ≤20 wt. %, preferably ≥5 to ≤15 wt. % organic vehicle.

### Method of Preparing a Conductive Paste

Typically, the conductive paste is prepared by mixing together the above-described components of the solids portion and the components of the organic vehicle, in any order. In a further preferred aspect, the present invention provides a process for preparing a conductive paste according to the first aspect, wherein the process comprises mixing together the above-described components of the solids portion and the components of the organic vehicle, in any order.

In some embodiments, the method of preparing the conductive paste comprises co-milling the substantially crystalline particles of one or more metal compounds and the glass frit particles of the inorganic particle mixture before they are mixed with the organic vehicle and the electrically conductive material.

In some embodiments, the method of preparing the conductive paste comprises first milling glass frit to produce coarse particles of glass frit, and then co-milling the coarse glass frit particles with substantially crystalline particles of one or more metal compounds to produce the inorganic particle mixture. The person skilled in the art will be able to select suitable equipment and milling conditions to produce the desired particle size and particle size distribution of the inorganic particle mixture.

In some embodiments, the conductive paste of the present invention is preferably substantially lead-free, that is, any lead-containing components are substantially absent from the paste. For example, the conductive paste may comprise less than 1 wt. % lead.

### Manufacture of an Electrode and Solar Cell

The skilled person is familiar with suitable methods for the manufacture of electrodes of a solar cell. Similarly, the skilled person is familiar with suitable methods for the manufacture of a solar cell. The conductive paste of the present invention may be employed to prepare a backside electrode or a front side electrode (i.e. light receiving side) of a solar cell. Preferably, the conductive paste of the present invention is employed to prepare a front side electrode of a solar cell.

The method for the manufacture of a frontside electrode of a solar cell typically comprises applying a conductive paste onto the surface of a semiconductor substrate, and firing the applied conductive paste.

The conductive paste may be applied to the semiconductor substrate by any suitable method. For example, the conductive paste may be applied by printing, such as by screen printing, stencil printing or inkjet printing. In screen printing methods, conductive pastes may be forced through a screen stencil (for example, using a squeegee) onto the surface of the substrate.

The conductive paste of the present invention may be applied onto a semiconductor substrate to form a front-side electrode of a solar cell. The solar cell may be an n-type or a p-type solar cell. The paste may be applied onto an n-type emitter (in a p-type solar cell), or onto a p-type emitter (in an n-type solar cell). The paste may be applied onto mono- or multicrystalline semiconductor substrates. The semiconductor substrate may be a silicon substrate. Alternative substrates include CdTe. The surface texture of crystalline substrates may vary depending on the manufacturing method employed. For example, the surface may comprise micron-sized, or nano-sized surface features, such as pyramids, inverted pyramids, wells or rods. Such surface features may be formed, for example, by metal catalysed chemical etching (MCCE) or by reactive ion etching (RIE). Examples of such texturized crystalline substrates include slurry-cut silicon wafers and diamond wire-cut silicon (DWS) wafers (both also referred to as “black silicon wafer”).

In some embodiments, the solar cell may comprise passivated emitter rear contact (PERC). Alternative solar cells are known as back junction cells. In this case, it may be preferred that the conductive paste of the present invention is applied to the back-side surface of the semiconductor substrate of the solar cell. Such a back side surface is typically covered with an insulating passivation layer (e.g. SiN layer), similar to the anti-reflective coating applied to the light receiving surface of the semiconductor substrate of the solar cell. Alternatively, the conductive paste may be applied to a thin film solar cell or the conductive paste may be applied to a substrate for an electronic device other than a solar cell.

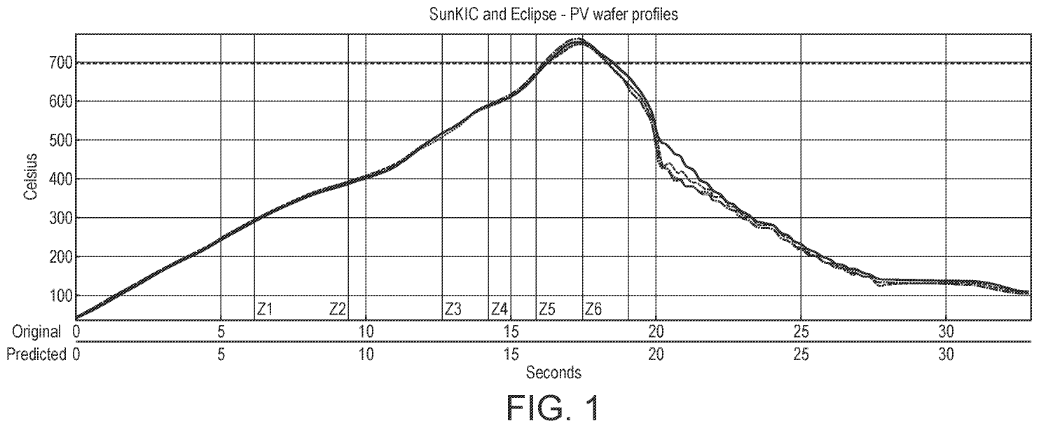

The skilled person is aware of suitable techniques for firing the applied conductive paste. An example firing curve is shown in FIG. 1. A typical firing process lasts approximately 30 seconds, with the surface of the electrode reaching a peak temperature of about 800° C. Typically, the furnace temperature will be higher to achieve this surface temperature. For example, the peak surface temperature of the electrode may be 1200° C. or less, 1100° C. or less, 1000° C. or less, 950° C. or less or 900° C. or less. The peak surface temperature of the electrode may be at least 600° C.

The semiconductor substrate may comprise an insulating layer on a surface thereof. Typically, the conductive paste of the present invention is applied on top of the insulating layer to form the electrode. Typically, the insulating layer will be non-reflective. A suitable insulating layer is SiN_{X} (e.g. SiN). Other suitable insulating layers include Si₃N₄, SiO₂, Al₂O₃ and TiO₂.

Methods for the manufacture of a p-type solar cell typically comprise applying a back side conductive paste (e.g. comprising aluminium) to a surface of the semiconductor substrate, and firing the back side conductive paste to form a back side electrode. The back side conductive paste is typically applied to the opposite face of the semiconductor substrate from the front side electrode.

In the manufacture of p-type solar cells, typically, the back side conductive paste is applied to the back side (non-light receiving side) of the semiconductor substrate and dried on the substrate, after which the front side conductive paste is applied to the front side (light-receiving side) of the semiconductor substrate and dried on the substrate. Alternatively, the front side paste may be applied first, followed by application of the back side paste. The conductive pastes are typically co-fired (i.e. the substrate having both front- and back-side pastes applied thereto is fired), to form a solar cell comprising front- and back-side conductive tracks.

The efficiency of the solar cell may be improved by providing a passivation layer on the back side of the substrate. Suitable materials include SiN (e.g. SiN), Si₃N₄, Si₂, Al₂O₃ and TiO₂. Typically, regions of the passivation layer are locally removed (e.g. by laser ablation) to permit contact between the semiconductor substrate and the back side conductive track. Alternatively, where pastes of the present invention are applied to the back side, the paste may act to etch the passivation layer to enable electrical contact to form between the semiconductor substrate and the conductive track.

### Examples

The invention will now be illustrated by reference to the following non-limiting examples.

### Glass Frit Preparation

Glass frits were prepared using commercially available raw materials. The composition of each glass frit is given in Table 1 below. Each glass frit was made according to the following procedure.

Raw materials for the glass were mixed using a laboratory mixer. One hundred grams of the mixture was melted in a ceramic crucible, in an electrical laboratory furnace. The crucible containing the raw material mixture was placed in the furnace while it was still cold, to avoid thermal shock and cracking of the ceramic crucible. The melting was carried out at 950-1100° C. in air. The molten glass was quenched in water to obtain glass frit. The glass frit was dried overnight in a heating chamber at 120° C.

Each glass frit was dry milled in a planetary mill to produce coarse ground glass frit having a D₁₀₀ particle size of 200 μm.

TABLE 1
Glass frit compositions

| | Content mol % | | | | | |
|---|---|---|---|---|---|---|
| Frit | TeO₂ | Li₂O | Na₂O | BaO | Ce₂O₃ | Bi₂O₃ |
| FRIT A | 59.9 | 16.3 | 6.3 | 3.8 | 3.4 | 10.3 |
| FRIT B | 90.9 | 9.1 | — | — | — | — |
| FRIT C | 95.0 | — | — | 5.0 | — | — |
| FRIT D | 95.5 | — | — | — | 4.5 | — |

### Preparation of Inorganic Blends

Inorganic blend (i) was prepared by co-milling crystalline particles of TeO₂, Li₂CO₃, Na₂CO₃, BaCO₃, Ce₂O₃ and Bi₂O₃ in the quantities required to provide an inorganic blend having an overall elemental composition matching that of Frit A. In the case of Li₂CO₃, Na₂CO₃, BaCO₃ the quantities were such to supply an equivalent molar quantity of the metal had the oxide of that metal been supplied at the recited mol %.

Inorganic blends (ii) to (v) were prepared by wet milling Frits A to D, respectively.

Inorganic blends (vi) to (viii), (each an inorganic particle mixture as required by the paste of the present invention), were prepared by co-milling particles of a glass frit (as prepared above) with the required crystalline components (i.e. compounds of metals not already present in the frit composition) in appropriate quantities to provide an inorganic blend having an overall chemical composition matching that of inorganic particle Frit A. Where non-oxide crystalline components were employed, the quantities were such to supply an equivalent molar quantity of the metal had the oxide of that metal been supplied at the recited mol %.

The composition of each inorganic blend in mol % is shown in Table 2.

TABLE 2
Composition of each inorganic blend

| | | Overall Inorganic Blend composition | | | | | |
|---|---|---|---|---|---|---|---|
| Inorganic | | (mol %) | | | | | |
| Blend | Components | TeO₂ | Li₂O | Na₂O | BaO | Ce₂O₃ | Bi₂O₃ |
| (i) | Crystalline TeO₂, Li₂CO₃, Na₂CO₃, | 59.9 | 16.3 | 6.3 | 3.8 | 3.4 | 10.3 |
| | BaCO₃, Ce₂CO₃ and Bi₂O₃ | | | | | | |
| (ii) | Frit A | 59.9 | 16.3 | 6.3 | 3.8 | 3.4 | 10.3 |
| (iii) | Frit B | 90.9 | 9.1 | — | — | — | — |
| (iv) | Frit C | 95.0 | — | — | 5.0 | — | — |
| (v) | Frit D | 95.5 | — | — | — | 4.51 | — |
| (vi) | Frit B + crystalline Na₂CO₃, | 59.9 | 16.3 | 6.3 | 3.8 | 3.4 | 10.3 |
| | BaCO₃, Ce₂O₃ and Bi₂O₃ | | | | | | |
| (vii) | Frit C + crystalline Li₂CO₃, | 59.9 | 16.3 | 6.3 | 3.8 | 3.4 | 10.3 |
| | Na₂CO₃, Ce₂O₃ and Bi₂O₃ | | | | | | |
| (viii) | Frit D + crystalline Li₂CO₃, | 59.9 | 16.3 | 6.3 | 3.8 | 3.4 | 10.3 |
| | Na₂CO₃, BaCO₃ and Bi₂O₃ | | | | | | |

For all inorganic blends, the wet milling was carried out in a planetary mill to provide a homogeneous inorganic blend having a D₅₀ particle size less than 1 μm (determined using a laser diffraction method using a Malvern Mastersizer 2000). Wet milling was carried out in Dowanol DPM solvent.

Crystalline TeO₂, Li₂CO₃, Na₂CO₃, BaCO₃, Ce₂O₃ and Bi₂O₃ raw materials in particulate form were obtained commercially.

### Paste Preparation

Conductive pastes each comprising a conductive metal, an inorganic blend prepared as described above and an organic vehicle were prepared in accordance with the following general method.

88 wt % of a mixture of two commercial silver powders, 2 wt % inorganic blend and 10 wt % of standard organic vehicle were pre-mixed and the resulting mixture was passed through a triple roll mill until a homogeneous paste was formed.

The mixture of two commercially available silver powders consisted of 4 wt % of powder A and 96 wt. % of powder B. Both powder A and Powder B comprise a hydrophobic coating. Powder A has an average particle size of less than 0.8 μm and powder B has an average particle size of less than 1.9 μm. Powder A and powder B both have tap density greater than 5 g/mL.

### Preparation of Solar Cells

Multicrystalline wafers with sheet resistance of 90 Ohm/sq and being 6 inch² in size, were screen printed on their back side with commercially available aluminum paste and dried in an infra-red mass belt. Each multicrystalline wafer was screen printed with a front side conductive silver paste prepared as described above.

The screens used for the front side pastes had finger openings of 34 μm. After printing the front side, the cells were dried in the infra-red mass belt dryer and fired in a Despatch belt furnace. The Despatch furnace had six firing zones with upper and lower heaters. The first three zones were held at around 500° C., the fourth and fifth zone are at a higher temperature and the sixth zone held at a maximum temperature of 975° C. (furnace temperature). The furnace belt speed was 610 cm/min. An example firing profile is shown in FIG. 1. The recorded temperature was determined by measuring the temperature at the surface of the solar cell during the firing process using a thermocouple.

Testing of Solar Cells Prepared from Conductive Pastes

Fill factor indicates the performance of the solar cell relative to a theoretical ideal (0 resistance) system. The fill factor correlates with the contact resistance—the lower the contact resistance the higher the fill factor will be. But if the inorganic particle mixture of the conductive paste is too aggressive it could damage the pn junction of the semiconductor. In this case the contact resistance would be low but due to the damage of the pn junction (recombination effects and lower shunt resistance) a lower fill factor would occur. A high fill factor therefore indicates that there is a low contact resistance between silicon wafer and the conductive track, and that firing of the paste on the semiconductor has not negatively affected the pn junction of the semiconductor (i.e. the shunt resistance is high).

Eta represents the efficiency of the solar cell, comparing solar energy in to electrical energy out. Small changes in efficiency can be very valuable in commercial solar cells.

The series resistance represents the sum of the electrical resistances of particular components of the solar cell. Increases in series resistance may result in a direct decrease in fill factor.

After firing the wafers were cooled. After cooling the fired solar cells were tested in an I-V curve tracer from Halm GmbH, model cetis PV-CTL1. The results are shown in Table 3 below. The results shown in Table 3 are provided by the I-V curve tracer, either by direct measurement or calculation using its internal software.

To minimize the influence of the contact area each cell was printed using the same screen and the same viscosity paste in each individual test set; this ensured that the line width printed onto each wafer was substantially identical and had no influence on the measurements presented herein.

TABLE 3
Solar cells testing results

| | Inorganic | Fill Factor | Eta | Series Resistance |
|---|---|---|---|---|
| Example | Blend | (rel %) | (rel %) | (rel %) |
| CE1 | (i) | 100.0 | 100.0 | 100.0 |
| CE2 | (ii) | 101.0 | 99.9 | 100.1 |
| CE3 | (iii) | not measurable | 21.5 | 3511.5 |
| CE4 | (iv) | not measurable | 10.5 | 7237.6 |
| Ex. 1 | (vi) | 100.6 | 100.7 | 88.8 |
| Ex. 2 | (vii) | 100.7 | 101.1 | 87.0 |
| Ex. 3 | (viii) | 99.6 | 100.2 | 98.6 |

The examples show that when pastes according to the present invention are used to prepare solar cells, the resulting solar cells have higher efficiency and lower series resistance as compared to solar cells prepared from conductive pastes with inorganic blends comprising only crystalline metal compounds or only glass frits. Furthermore, the examples demonstrate that when conductive pastes were prepared using an inorganic blend comprising only Frit B or Frit C that not only could the fill factor not be measured, but very low cell efficiencies and very high series resistances were obtained.

Most notably, whilst the inorganic blends used to prepare the solar cells of CE1, CE2 and Examples 1-3 all have the same overall chemical composition, the solar cells of Examples 1 to 3 have lower series resistance and higher cell efficiency.

1. A conductive paste for forming a conductive track or coating on a substrate, the paste comprising a solids portion dispersed in an organic vehicle,
the solids portion comprising electrically conductive material and an inorganic particle mixture;
wherein the inorganic particle mixture comprises particles of glass frit and substantially crystalline particles of one or more metal compounds;
wherein the glass frit comprises greater than 90 mol % TeO₂ and one or more of an alkali metal oxide, an alkaline earth metal oxide, an oxide of cerium, and an oxide of bismuth,
wherein the substantially crystalline particles of one or more metal compounds comprise one or more of a lithium compound, a sodium compound, a potassium compound, a barium compound, a cerium compound and a bismuth compound, and
wherein the conductive paste is lead-free.

2. A conductive paste according to claim 1 wherein the glass frit comprises at least 91 mol % TeO₂, preferably at least 92 mol % TeO₂, more preferably at least 95 mol % TeO₂.

3. (canceled)

4. (canceled)

5. A conductive paste according to claim 1 wherein the glass frit is substantially free of silicon oxide.

6. A conductive paste according to claim 1 wherein the inorganic particle mixture comprises particles of glass frit in an amount of at least 25 wt. %, at least 40 wt. %, at least 45 wt. %, or at least 50 wt. %.

7. A conductive paste according to claim 1 wherein the inorganic particle mixture comprises particles of glass frit in an amount of 75 wt. % or less, 70 wt. % or less, 65 wt. % or less, or 60 wt. % or less.

8. (canceled)

9. A conductive paste according to claim 1 wherein the substantially crystalline particles of one or more metal compounds comprise one or more compounds selected from metal oxides, metal carbonates, metal nitrates, metal hydrogen carbonates, metal oxalates, metal acetates, metal and/formates.

10. A conductive paste according to claim 1 wherein the substantially crystalline particles of one or more metal compounds comprise one or more of Li₂CO₃, Na₂CO₃, BaCO₃, Ce₂O₃ and Bi₂O₃.

11. A conductive paste according to claim 1 wherein the inorganic particle mixture comprises substantially crystalline particles in a total amount of at least 20 wt. %, at least 25 wt. %, at least 30 wt. %, at least 35 wt. %, or at least 40 wt. %.

12. A conductive paste according to claim 1 wherein the inorganic particle mixture comprises substantially crystalline particles in a total amount of 75 wt. % or less, 60 wt. % or less, 55 wt. % or less, or 50 wt. % or less.

13. A process for producing a conductive paste according to claim 1 comprising mixing an organic vehicle, an electrically conductive material and the components of the inorganic particle mixture, in any order.

14. A process according to claim 13 comprising the step of co-milling the components of the inorganic particle mixture before they are mixed with the organic vehicle and the electrically conductive material.

15. A process for producing a solar cell comprising applying a conductive paste according to claim 1 to a semiconductor substrate, and firing the applied conductive paste.

16. (canceled)

17. (canceled)

18. Use of a conductive paste according to claim 1 in the manufacture of an electrode of a solar cell.

19. (canceled)
